(19) United States
(12) Patent Application Publication
(10) Pub. No.: US 2014/0285990 A1
(43) Pub. Date: Sep. 25, 2014

(54) CIRCUIT BOARD FOR CONNECTING SECONDARY BATTERY

(71) Applicant: Samsung SDI Co., Ltd., Yongin-si (KR)

(72) Inventors: Hyung-Sin Kim, Yongin-si (KR); Ji-Yeon Choi, Yongin-si (KR); Seok-Bong Lee, Yongin-si (KR); Sang-Joo Lee, Yongin-si (KR)

(73) Assignee: Samsung SDI Co., Ltd., Yongin-si (KR)

(21) Appl. No.: 14/225,098

(22) Filed: Mar. 25, 2014

(30) Foreign Application Priority Data
Mar. 25, 2013 (KR) 10-2013-0031507

(51) Int. Cl. H01M 2/10; H05K 1/18

(52) U.S. Cl. CPC H01M 2/1011; H05K 1/181
USPC 361/767; 174/268; 174/258; 174/257

(57) ABSTRACT

A circuit board for connecting a secondary battery including a first insulation layer, a conductive layer positioned on one surface of the first insulation layer, and a pad layer positioned on the conductive layer and divided into at least two areas is disclosed. In the circuit board, the conductive layer has an area wider than that of the pad layer. Accordingly, the conductive layer has an area wider than that of the pad layer, so that it is possible to miniaturize the circuit board and to improve the safety of the circuit board.

### CROSS-REFERENCE TO RELATED APPLICATIONS

This application claims priority to and the benefit of Korean Patent Application No. 10-2013-0031507, filed on Mar. 25, 2013, in the Korean Intellectual Property Office, the entire content of which is incorporated herein by reference.

### BACKGROUND

1. Field of the Invention

The described technology generally relates to a circuit board for connecting a secondary, or rechargeable, battery.

2. Description of the Related Technology

Secondary batteries, also known as rechargeable batteries, have been used as power sources of portable electronic devices. Because secondary batteries can be recharged, they are generally more environmentally and economically friendly. As more electronic devices become more portable, the use of secondary batteries increases. Furthermore, secondary batteries are used in a wider array of fields, the demands on those batteries increases.

A popular choice for secondary batteries is Li-ion technology. Li-ion batteries can be compact in size, lightweight, high power and high capacity.

It would be desirable to reduce the size and weight of secondary batteries so that electronic devices can also be reduced in size and weight. Since there is a highly reactive material used in secondary batteries such as lithium inside the secondary battery, there is a limitation in safely decreasing the size and weight of the secondary battery. To decrease the size and weight of electronic devices, it would be advantageous to decrease the size and weight of the batteries. However, decreasing the size of the batteries can pose a safety issue. There have been many attempts at decreasing the size and weight of secondary batteries while improving the safety of the batteries.

### SUMMARY

One inventive aspect is a circuit board connecting a secondary battery, which can safely miniaturize the secondary battery. Several embodiments further provide for a circuit board for connecting a secondary battery, in a manner that allows the design of the secondary battery to be simplified.

In one embodiment, there is a circuit board for connecting a secondary battery, including: a first insulation layer; a conductive layer positioned on one surface of the first insulation layer; and a pad layer positioned on the conductive layer and divided into at least two areas, wherein the conductive layer has an area wider than that of the pad layer.

The conductive layer may include a first and second conductive layer spaced apart from each other. A pad layer may be positioned on the first and second conductive layers.

The pad layer positioned on the first conductive layer and the pad layer positioned on the second conductive layer may have different polarities.

The circuit board may further include a second insulation layer positioned on the conductive layer so as to divide the pad layer into at least two areas.

The first insulation layer may include a first and second area. The conductive layer may be positioned on the first area of the first insulation layer. The circuit board may further include a third insulation layer positioned on the second area of the first insulation layer.

The upper height of the second insulation layer may be higher than that of the pad layer.

The upper height of the second insulation layer may be identical to that of the third insulation layer.

The second and third insulation layers may be made of the same material.

The second and third insulation layers may be photo solder resists.

The pad layer may include first and second pad layers divided and spaced apart from each other. In one embodiment the first and second pad layers may form an angled from one another.

The conductive layer may have several different shapes for example a bend, a triangular, or a trapezoid shape.

The pad layer may include nickel or gold. The pad layer can be connected via soldering to a wire or connector.

In one embodiment, the circuit board may further include an electronic device positioned on the other surface of the first insulation layer.

In one embodiment, the pad layer and the conductive layer can be positioned on different planes of the insulation layer, to miniaturize the circuit board. In addition, the conductive layer is configured to have an area wider than that of the pad layer, so that it is possible to prevent damage of the electronic device, thereby securing the safety of the circuit board.

Further, the conductive layer is can have a bent shape or a triangular or trapezoid shape, and the pad layers can be spaced apart from each other on the conductive layer, so that the connection direction of the wire is implemented to have two or more directions, thereby providing convenience in the design of the secondary battery.

### BRIEF DESCRIPTION OF THE DRAWINGS

FIG. 1 shows a plan view of a circuit board for connecting a secondary battery according to one embodiment.

FIG. 2 shows a sectional view taken along line A-A′ of the circuit board shown in FIG. 1.

FIG. 3 shows a plan view of a circuit board compared with the circuit board according to another embodiment.

FIG. 4 shows a sectional view taken along line B-B′ of the circuit board shown in FIG. 3.

FIG. 5 shows a plan view of another circuit board compared with the circuit board according to another embodiment.

FIG. 6 shows a sectional view taken along line C-C′ of the circuit board shown in FIG. 5.

FIGS. 7 and 8 show plan views showing a how a wire can be connected to the circuit board shown in FIG. 1.

FIG. 9 shows a plan view of a circuit board for connecting a secondary battery according to another embodiment.

FIG. 10 shows a sectional view taken along line D-D′ of the circuit board shown in FIG. 9.

FIGS. 11 and 12 show plan views of circuit boards for connecting a secondary battery according to another embodiments.

### DETAILED DESCRIPTION

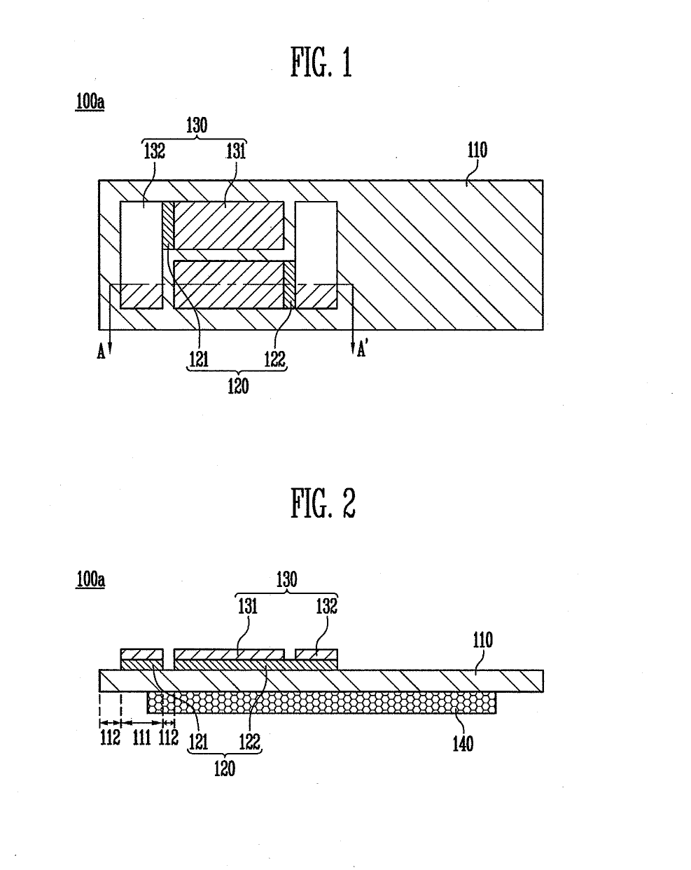

FIG. 1 shows a plan view of a circuit board 100a for connecting a secondary battery according to one embodiment. FIG. 2 shows a sectional view taken along line A-A′ of the circuit board 100a shown in FIG. 1.

As shown in FIGS. 1 and 2, the circuit board 100a can include a first insulation layer 110, a conductive layer 120 positioned on one surface of the first insulation layer 110, and a pad layer 130 positioned on the conductive layer 120.

The first insulation layer 110 can become a base for the circuit board 100a. The first insulation layer 110 can be made of FR4.

Here, the first insulation layer 110 may have one surface and the other surface opposite to the one surface. The conductive layer 120 may be positioned on the one surface of the first insulation layer 110, and an electronic device 140 may be positioned on the other surface of the first insulation layer 110. The one surface of the first insulation layer 110 may include first and second areas 111 and 112. In one embodiment the conductive layer 120 can be over the first area 111 while not over the second area 112.

In one embodiment, the conductive layer 120 is positioned on the one surface of the first insulation layer 110.

Here, the conductive layer 120 may include a portion of a circuit pattern of the circuit board 100a. The conductive layer 120 may be electrically connected to the electronic device 140 positioned on the other surface of the first insulation layer 110 through another circuit pattern.

Meanwhile, the conductive layer 120 may be divided into at least two areas. The conductive layer 120 may include a first conductive layer 121 and a second conductive layer 122. In this case, the first and second conductive layers 121 and 122 may be implemented to have different electrical polarities. For example, the first conductive layer 121 may be connected to a positive electrode terminal of a bare cell so as to have a positive polarity, and the second conductive layer 122 may be connected to a negative electrode terminal of the bare cell so as to have a negative polarity.

The conductive layer 120 may have a bent shape. For example, the first conductive layer 121 may have a ‘L’ shape, and the second conductive layer 122 may have a shape vertically symmetric to the first conductive layer's ‘L’ shape. The conductive layer 120 may be made of copper, as copper is both electrically and thermally conductive. The conductive layer 120 can have a box shape by combining the ‘L’ shapes of the respective first and second layers 121 and 122.

In one embodiment, the pad layer 130 is positioned on the conductive layer 120. The pad layer can be divided into at least two areas.

Here, the pad layer 130 includes a pad layer 130 positioned on the first conductive layer 121 and a pad layer 130 positioned on the second conductive layer 122, and may be divided into two areas on one conductive layer 120. That is, first and second pad layers 131 and 132 may be divided while being spaced apart from each other on each conductive layer 120. Meanwhile, the first and second pad layers 131 and 132 may be spaced apart from each other at a bent portion of the conductive layer 120. Thus, the first and second pad layers 131 and 132, as shown in FIG. 1, can form an angle based on their long sides, i.e., a perpendicular or rectangular shape. The first and second pad layers 131 and 132 may form a diagonal shape.

The pad layers 130 formed on the respective conductive layers 120 may have different polarities. For example, the first and second pad layers 131 and 132 formed on the first conductive layer 121 may have a positive polarity, and the first and second pad layers 131 and 132 formed on the second conductive layer 122 may have a negative polarity. In this case, the first and second pad layers 131 and 132 positioned on one conductive layer 120 may have the same polarity. This is because the first and second pad layers 131 and 132 can be electrically connected to each other through the same conductive layer 120 positioned there beneath.

A wire or connector of an external device may be directly soldered to the pad layer 130, and therefore, the pad layer 130 may include metal, e.g., nickel or gold, which has excellent electrical conductivity while being suitable for soldering. In this case, the pad layer 130 is not necessarily formed into a single-layered structure, but may be formed into a multi-layered structure. For example, the pad layer 130 may be configured with two layers in which one layer includes nickel and the other layer includes gold.

Meanwhile, referring to FIGS. 1 and 2, it can be seen that the conductive layer 120 according to this embodiment has an area wider than that of the pad layer 130 formed on the conductive layer 120. This is because the pad layers 130 are formed to be spaced apart from each other on the conductive layer 120, which is a structure capable of solving conventional problems. Hereinafter, the structure will be described in detail.

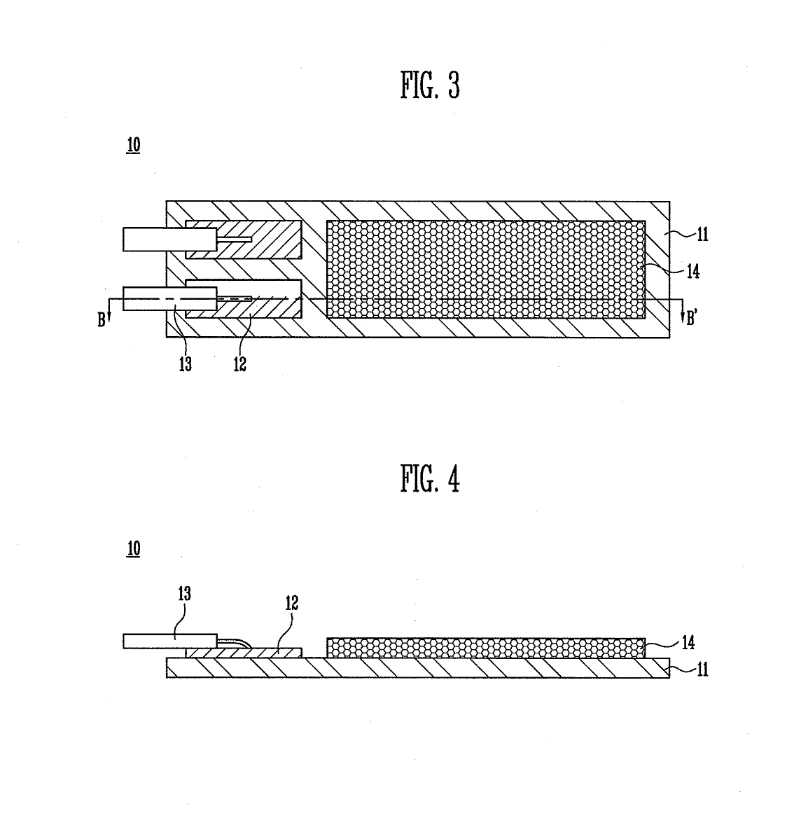

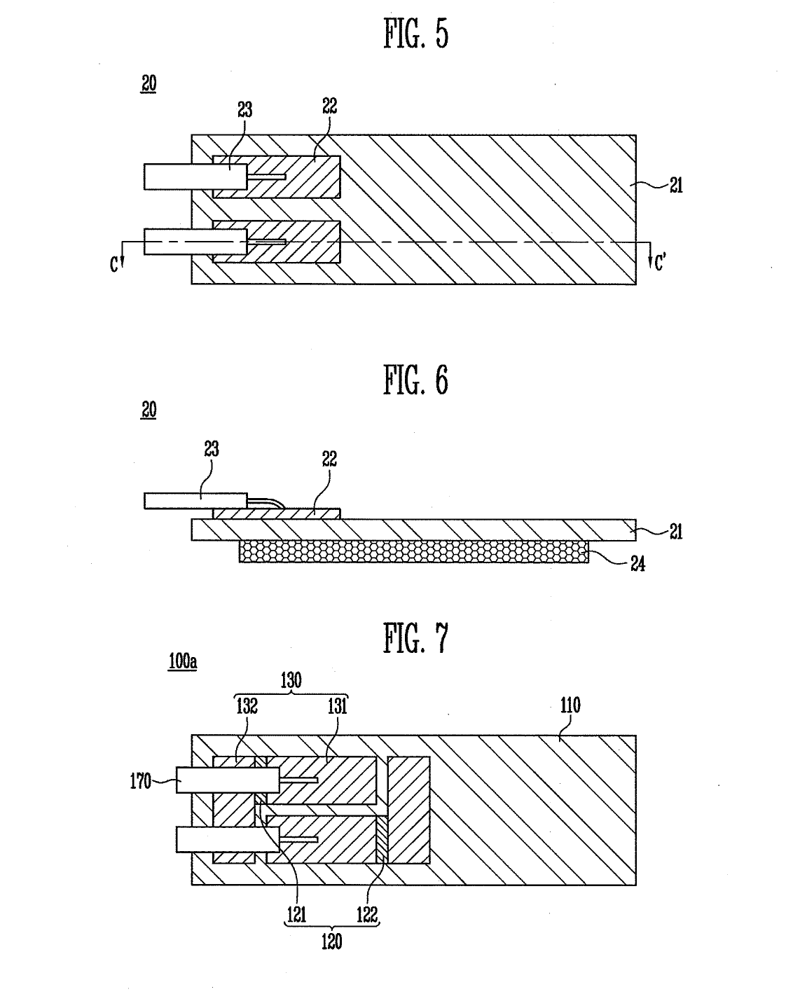

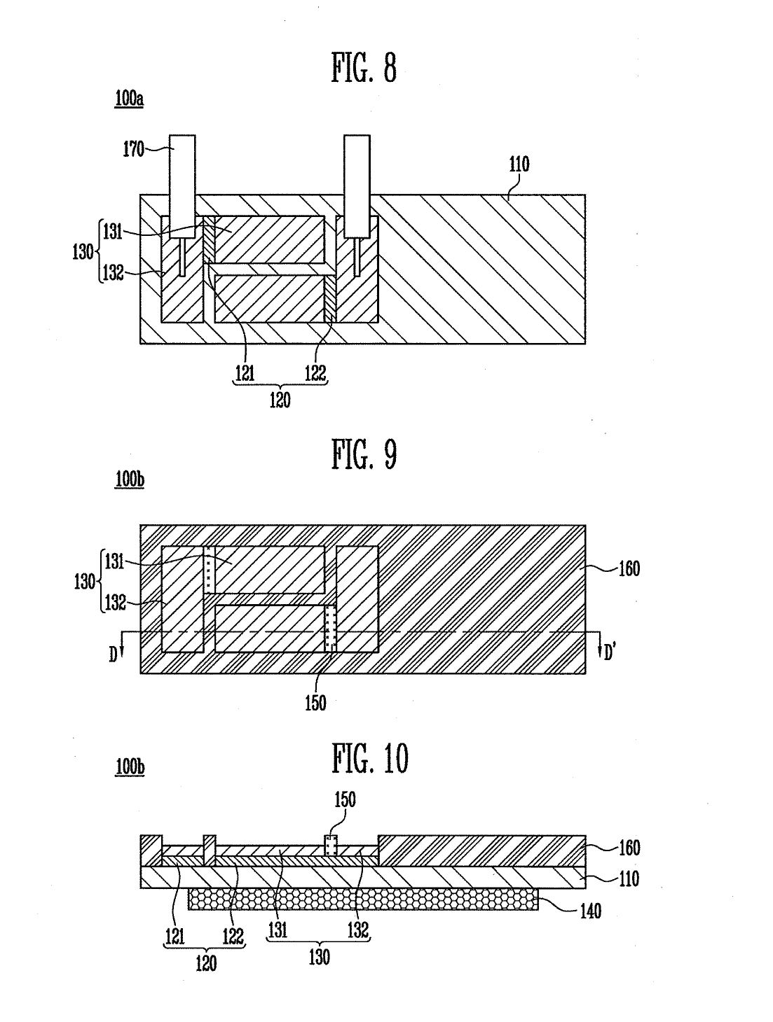

FIG. 3 shows a plan view of a circuit board 10 compared with the circuit board 100a according to one. FIG. 4 is a sectional view taken along line B-B′ of the circuit board 10 shown in FIG. 3. FIG. 5 is a plan view of another circuit board 20 compared with the circuit board 100a according to another embodiment. FIG. 6 is a sectional view taken along line C-C′ of the circuit board 20 shown in FIG. 5. FIGS. 7 and 8 are plan views showing a state in which a wire 170 is connected to the circuit board 100a shown in FIG. 1.

In the circuit board 10 shown in FIGS. 3 and 4, a pad portion 12 and an electronic device 14 may be positioned on the same plane of an insulation layer 11, and a wire 13 may be connected to the pad portion 12. In this case, the electronic device 14 has a certain size, and therefore, the size of the circuit board 10 can be increased when the pad portion 12 and the electronic device 14 can be positioned on the same plane. In order to solve such a problem, it may be desirable to have a pad portion 22 and an electronic device 24 positioned on different planes of an insulation layer 21 as shown in FIGS. 5 and 6. In the circuit boards 10 and 20 shown in FIGS. 3 to 6, both the pad portions 11 and 22 can be formed in any one direction, and hence the wires 13 and 23.

However, in the circuit board 100a the conductive layer 120 and the pad layer 130 can be positioned on a different plane from the electronic device 140, to miniaturize the circuit board 100a and to minimize heat conducted to the electronic device 140.

Referring to FIGS. 2 and 7, the wire 170 can be connected to any one of the first and second pad layers 131 and 132, the heat generated by soldering of the wire 170 can be widely spread through the conductive layer 120 having an area wider than that of the pad layer 130, thereby reducing the heat conducted to the electronic device 140. For example, in a case where the wire 170 is connected to the first pad layer 131 as shown in FIG. 7, the heat generated by the soldering can be conducted to a lower portion of the second pad layer 132. Accordingly, a portion of the heat can be emitted through the pad layer 130, and the heat can be spread through the wide conductive layer 120. Thus, the damage of the electronic device 140 can be minimized.

Moreover, in a case where the conductive layer 120 has a bend shape in this embodiment, the first and second pad layers 131 and 132 may be formed to be inclined to each other. Hence, the wire 170 can be connected to the first pad layer 131 as shown in FIG. 7. Alternatively, the wire 170 may be connected to the second pad layer 132 as shown in FIG. 8. That is, the direction in which the wire 170 is approached may be divided into two directions, so that it is possible to provide convenience in the design of a battery pack. The reason why the wire 170 can be approached in different directions is that the conductive layer 120 has the bent shape, and the first and second pad layers 131 and 132 positioned on one conductive layer 120 have the same polarity.

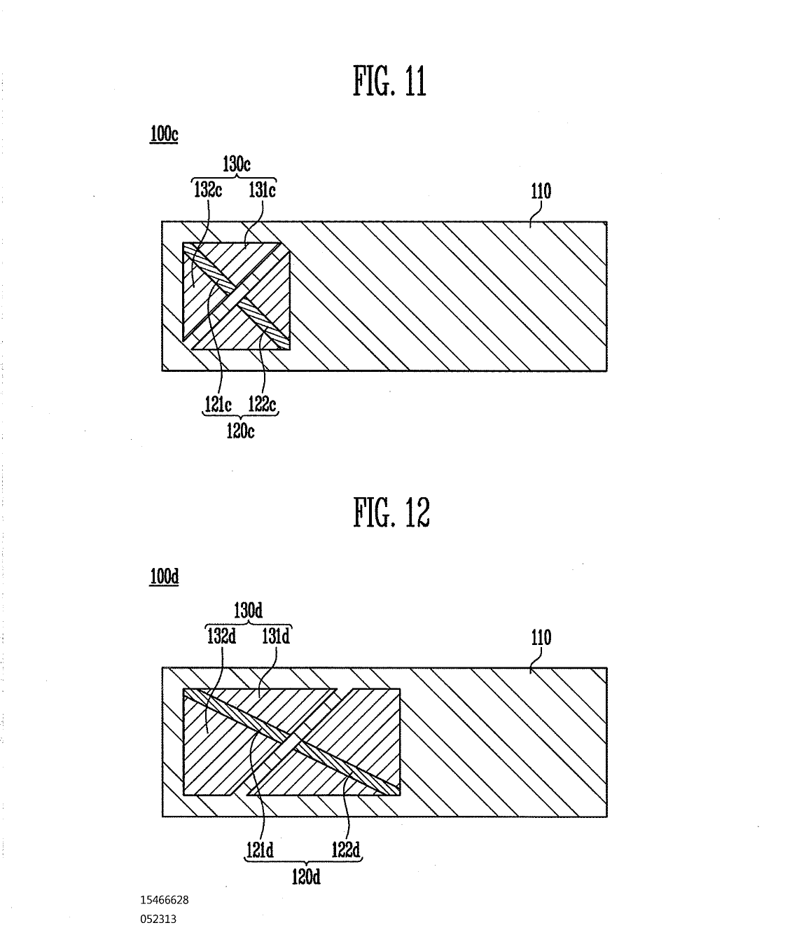

FIG. 9 shows a plan view of a circuit board 100b for connecting a secondary battery. FIG. 10 shows a sectional view taken along line D-D′ of the circuit board 100b shown in FIG. 9. Hereinafter, the circuit board 100b according to this embodiment will be described with reference to FIGS. 9 and 10.

The circuit board 100b includes a first insulation layer 110, a conductive layer 120 and a pad layer 130. The circuit board 100b may include both second and third insulation layers 150 and 160 or may include any one of the second and third insulation layers 150 and 160.

The second insulation layer 150 is a member that divides the pad layer 130 into two areas. The second insulation layer 150 may be positioned on the conductive layer 120 at the position where the pad layer 130 is divided into the two areas. In this case, the upper height of the second insulation layer 150 may be higher than that of the pad layer 130. The second insulation layer 150 may perform a function of preventing a solder member from overflowing when the wire 170 is soldered.

The third insulation layer 160 may be positioned on a second area of the first insulation layer 110, in which the conductive layer 120 is not formed. The third insulation layer 160 may be implemented in a shape surrounding the circumference of the conductive layer 120. The upper height of the third insulation layer 160 may be identical to that of the second insulation layer 150. Accordingly, the upper height of the third insulation layer 160 is higher than that of the pad layer 130, and thus the third insulation layer 160 can prevent a solder member from overflowing when the wire 170 is soldered.

Meanwhile, the second and third insulation layers 150 and 160 may be made of the same material. For example, the second and third insulation layers 150 and 160 may be photo solder resists. The pad layers 130 divided into two areas by the second insulation layer 150 and the conductive layers 120 divided into two areas by the third insulation layer 160 can be clearly partitioned, and accordingly, it is possible to prevent an undesired short circuit between the pad layer 130 and the conductive layer 120.

FIGS. 11 and 12 show a plan views of circuit boards 100c and 100d for connecting a secondary battery.

Conductive layers 120c and 120d may have a bent shape, but may have trapezoid shapes as shown in FIGS. 11 and 12. In this case, pad layers 130c and 130d respectively positioned on the conductive layers 120c and 120d may have a triangular or quadrangular shape. Although the pad layers 130c and 130d have the triangular or trapezoid shape in these embodiments, the wire 170 can be approached in two directions.

In the following detailed description, only certain exemplary embodiments of the present invention have been shown and described, simply by way of illustration. As those skilled in the art would realize, the described embodiments can be different modifications can be made without departing from the spirit or scope of the present invention. Accordingly, the drawings and description are to be regarded as illustrative in nature and not restrictive. When an element is referred to as being “on” another element, it can be directly on the another element or be indirectly on the another element with one or more intervening elements interposed there between. When an element is referred to as being “connected to” another element, it can be directly connected to the another element or be indirectly connected to the another element with one or more intervening elements interposed there between. Hereinafter, like reference numerals refer to like elements.

While the exemplary embodiment describes Li-ion batteries other types of secondary batteries can be used without departing from the scope of the invention.

While the present invention has been described in connection with certain exemplary embodiments, it is to be understood that there are other embodiment that would become apparent to one of ordinary skill in the art, including various modifications and equivalent arrangements included within the spirit and scope of the appended claims, and equivalents thereof.

What is claimed is:

1. A circuit board for connecting a secondary battery, comprising:
a first insulation layer;
a conductive layer positioned on one surface of the first insulation layer; and
a pad layer positioned on the conductive layer and divided into at least two areas,
wherein the conductive layer has an area wider than that of the pad layer.

2. The circuit board of claim 1, wherein the conductive layer includes a first portion and a second portion spaced apart from each other, and the pad layers are respectively positioned on the first and the second portion of the conductive layer.

3. The circuit board of claim 2, wherein the pad layer positioned on the first portion of the conductive layer and the pad layer positioned on the second portion of the conductive layer have different polarities.

4. The circuit board of claim 1, further comprising a second insulation layer positioned on the conductive layer so as to divide the pad layer into at least two areas.

5. The circuit, board of claim 4, wherein the first insulation layer includes a first area and a second area, and the conductive layer is positioned on the first area of the first insulation layer, and
wherein the circuit board further comprises a third insulation layer positioned on the second area of the first insulation layer.

6. The circuit board of claim 4, wherein the upper height of the second insulation layer is higher than that of the pad layer.

7. The circuit board of claim 5, wherein the upper height of the second insulation layer is identical to that of the third insulation layer.

8. The circuit board of claim 5, wherein the second and third insulation layers are made of the same material.

9. The circuit board of claim 8, wherein the second and third insulation layers are photo solder resists.

10. The circuit board of claim 1, wherein the pad layer includes first pad layer and second pad layer divided and spaced apart from each other, and the first and second pad layers form an angle based on long sides thereof.

11. The circuit board of claim 1, wherein the conductive layer has a bent shape.

12. The circuit board of claim 1, wherein the conductive layer has a triangular or trapezoid shape.

13. The circuit board of claim 1, wherein the pad layer includes nickel or gold.

14. The circuit board of claim 1, wherein a wire or connector is soldered to the pad layer.

15. The circuit board of claim 1, further comprising an electronic device positioned on the other surface of the first insulation layer.
